(19) United States
(12) Patent Application Publication
(10) Pub. No.: US 2007/0085583 A1
(43) Pub. Date: Apr. 19, 2007

(54) System for and method of automatically reducing power to a semiconductor device

(75) Inventor: Sharon Zohar, San Jose, CA (US)

Correspondence Address: Johnathan O. Owens;HAVERSTOCK & OWENS LLP, 162 North Wolfe Road, Sunnyvale, CA, 94086, US

(73) Assignee: ENVISION TECHNOLOGY, INC.

(21) Appl. No.: 11/582,895

(22) Filed: Oct. 17, 2006

Related U.S. Application Data
(60) Provisional application No. 60/728,147, filed on Oct. 18, 2005.

(51) Int. Cl. H03K 7/02; H03K 5/02

(52) U.S. Cl. 327/178

(57) ABSTRACT

A system for and method of reducing power consumed by an electronic system is disclosed. The system includes an energy controller for controlling power to one or more functional modules or regions on the electronic system. Each of the functional modules has an activity detector for determining whether any activity is occurring on the respective functional module. When an activity detector detects no activity on a functional module, the energy controller automatically reduces power or clock gating to that functional module after completing a computation. When activity is detected on the functional module, the energy controller automatically restores power to the functional module. Preferably, multiple functional modules, each having an activity detector, and the energy controller are contained on a single semiconductor die.

### RELATED APPLICATION

This application claims priority under 35 U.S.C. § 119(e) of the co-pending U.S. provisional patent application Ser. No. 60/728,147, filed Oct. 18, 2005, and titled “Automatic General Purpose Power Reduction Method for Semiconductor,” which is hereby incorporated by reference.

### FIELD OF THE INVENTION

This invention relates to semiconductor devices. More specifically, this invention relates to automatically reducing power consumed by semiconductor devices.

### BACKGROUND OF THE INVENTION

Today's semiconductor devices are increasingly used on products that require low power consumption. For example, semiconductor devices are used on wireless and portable products. These products, relatively small and lightweight, require small and lightweight power sources. To fit all their functionality in a small footprint, these products use densely packed semiconductor devices that generate excessive heat concentrated on small areas. Ever decreasing device geometries that also draw unnecessary power quickly drain batteries and other power sources and also result in heat-related damage.

These problems also plague other architectures, such as application specific integrated circuits (ASICs). ASIC circuitry are used on new technologies that require complex functionality. Accordingly, ASICs also have increased power requirements that also result in unnecessary power drain and heat-related damage.

Reducing both dynamic and static power consumption is now required on most semiconductor devices and, indeed, is often used as a marketing tool to differentiate between products. Reducing power consumption is a difficult challenge, especially when having to account for size reduction, architectures that must support complex functionality, and product delivery deadlines.

### SUMMARY OF THE INVENTION

Embodiments of the present invention are able to reduce power consumed on electronic circuits having one or more functional modules. In a first aspect of the present invention, a system for controlling power to one or more functional modules of a semiconductor device includes a first functional module from the one or more functional modules coupled to an energy controller. The first functional module contains a first activity detector. The energy controller is programmed to control power to the first functional module based on an output from the first activity detector. As used herein, the term “programmed” means hardwired, programmed using software or firmware, or configured in any other way that allows an electronic component to perform predetermined steps.

The first activity detector is coupled to one or more strategic points on the first functional module. Strategic points are those locations where signals are monitored. The one or more strategic points preferably include an input to the first functional module. The energy controller is programmed, preferably by hard-wired circuitry, to wait a predetermined number of successive clock cycles before controlling power to the first functional module such as by reducing power or gating a clock to the first functional module, turning off the clock to the first functional module, or by reducing power using other methods. The predetermined number of clock cycles correspond to a depth of a pipeline on the first functional module. The first activity detector is programmed to signal the energy controller to restore power to the first functional module when the first activity detector detects activity at any of the one or more strategic points.

Preferably, the system also includes a second functional module from the one or more functional modules. The second functional module contains a second activity detector coupled to the energy controller. The energy controller is also programmed to control power to the second functional module based on an output from the second activity detector. In one embodiment, the energy controller is also programmed to control power to the first functional module based on an output of the second activity detector.

Preferably, the first functional module, the second functional module, and the energy controller are formed on a single die. In one embodiment, the first and second functional modules are two processors in a multiprocessor architecture. In other embodiments, the first functional module is any one of an arithmetic module, a graphics module, and a digital signal processing module.

The first functional module also includes a power control block for controlling power to the first functional module. Preferably, the power control block includes a transistor coupling a power source to the first functional module. In other embodiments, the power control block includes any one or more of a control clock gating module, a power island, a footer transistor, a header transistor, a back bias module, a gate bias module, a voltage reduction module, and a clock speed reduction module, any of which couples the first functional module to a power source, a clock, or the like. Here, “modules” are used to describe elements that perform certain functions; for example, a control clock gating module is a module that performs control clock gating.

In a second aspect of the present invention, a method of controlling power to one or more functional modules on a semiconductor device includes monitoring activity on a first functional module from the one or more functional modules; determining that the first functional module has been inactive for a predetermined duration of time; and reducing power to the first functional module based on the inactivity for the predetermined duration of time. The duration corresponds to a depth of a pipeline on the first functional module.

The method also includes applying power to the first functional module when activity is detected at a strategic point on the semiconductor device. The strategic point is located on the first functional module or on a second functional module from the one or more functional modules. Preferably, the first functional module and the second functional module are formed on a single die.

In one embodiment, the first and second functional modules are two processors in a multiprocessor architecture. Alternatively, the first functional module is any one of an arithmetic module, a graphics module, and a digital signal processing module.

In a third aspect of the present invention, a method of generating a model of a semiconductor device having multiple functional modules includes generating a flop graph corresponding to multiple regions of the multiple functional modules of the semiconductor device; determining strategic points for monitoring activities within the multiple regions; inserting an energy control module for controlling power to each of the multiple regions based on the activity monitored at the strategic points; and generating a netlist corresponding to the semiconductor device.

In one embodiment, the energy control module includes an activity detector at each of the multiple regions coupled to a single energy controller. Each activity detector is programmed to raise a signal when activity in a region from the multiple regions is detected. The energy controller controls power to a region from the multiple regions in response to the signal.

The method also includes determining a wait time between detecting no activity and raising the signal. The wait time corresponds to a length of a pipeline for a region from the multiple regions. The method also includes inserting a hard-wired wait circuit for determining when the wait time has elapsed.

Preferably, the method also includes performing an optimization step for grouping the regions from the multiple regions based on an optimization parameter, such as a cost function. The optimization parameter is based on one or more of a number of interdependencies between multiple regions, depths of pipelines within the multiple regions, and a number of drivers for electronic circuitry within the multiple regions. Alternatively, or in addition, the optimization parameters are based on one or more of spacings between electronic components on the semiconductor device, distances between regions containing the electronic components, distances between a power source and the multiple regions, and a cost function, such as a function indicating the cost of fabricating a final semiconductor device. The method also includes forming a semiconductor device corresponding to the netlist.

In a fourth aspect of the present invention, a system for controlling power to multiple functional modules includes a first functional module, a second functional module, and a detection and control module coupled to both. The first and second functional modules are from the multiple functional modules. The second functional module contains a signal path that has an intermediate stage and an output stage that couples the intermediate stage to the first functional module. The detection and control module is programmed to detect activity along the intermediate stage and to control power to the first functional module based on the detected activity.

In one embodiment, the detection and control module includes an activity detector and a power control block. The activity detector is coupled to the intermediate stage and monitors signals along the intermediate stage. The power control block couples the first functional module to a power source. The energy controller is coupled to the activity detector and to the power control block. The energy controller is programmed to control the power control block to reduce power to the first functional module when no signal is detected for a pre-determined number of successive clock cycles along the intermediate stage and to apply power to the first functional module when a signal is detected along the intermediate stage.

The first and second functional modules are any one or more of co-processors, an arithmetic module, a graphics module, and a digital signal processing module. Preferably, the multiple functional modules are formed on a single semiconductor die.

In a fifth aspect of the present invention, a method of controlling power to first and second functional modules comprises monitoring activity along an intermediate stage of a signal path on the first functional module and controlling power to the second functional module based on the detected activity. The signal path also has an output stage that couples the first functional module to the second functional module. Power is controlled to the second functional module by applying power to the second functional module when activity is detected along the intermediate stage and reducing power to the second functional module when no activity is detected along the intermediate stage for a pre-determined period. Each of the first and second functional modules is a co-processor, an arithmetic module, a graphics module, or a digital signal processing module. Preferably, the first and second functional modules are formed on a single semiconductor die.

In a sixth aspect of the present invention, a semiconductor die includes multiple functional modules and one or more monitors for detecting activity on the multiple functional modules. Preferably, the semiconductor die also includes a controller for controlling the multiple functional modules in response to the detected activity. In one embodiment, the controller is programmed to control power to the multiple functional modules. In another embodiment, the controller is programmed to control loads, such as by balancing loads, to the multiple functional modules. As one example, all of the multiple functional modules are capable of performing the same tasks and thus form a distributed processing system. If activity is detected on one functional module by the one or more monitors (indicating that the functional modules is “busy”), a request to perform a task is routed to another of the functional modules.

### BRIEF DESCRIPTION OF THE DRAWINGS

FIG. 1 is a block diagram of an energy controller controlling power to four functional modules in accordance with the present invention.

FIG. 2 shows one embodiment of an activity detector in accordance with the present invention.

FIG. 3 shows a power control block for controlling power to the functional circuitry of the functional module of FIG. 1.

FIG. 4A is a block diagram of a semiconductor device with four functional modules, each with its own energy management system, in accordance with one embodiment of the present invention.

FIG. 4B is a block diagram of an exemplary energy management system of FIG. 4A, which includes an activity detector and an energy controller.

FIG. 5 is a flow chart for determining when to reduce power to a functional module in accordance with the present invention.

FIG. 6 is a logical diagram of a circuit for determining when to reduce power to a functional module in accordance with the present invention.

FIGS. 7-9 show components of three activity detectors in accordance with the present invention.

FIG. 10 is a block diagram of a system with a functional module having an energy controller coupled to the outputs of three other functional modules in accordance with one embodiment of the present invention.

FIG. 11 is a block diagram of a system with a functional module having an energy controller coupled to intermediate stages of three other functional modules in accordance with one embodiment of the present invention.

FIG. 12 is a flow chart of steps performed by a circuit modeling tool used to fabricate semiconductor devices in accordance with the present invention.

FIG. 13 is a flop graph generated by a circuit modeling tool used to fabricate semiconductor devices in accordance with the present invention.

### DETAILED DESCRIPTION OF A PREFERRED EMBODIMENT

Embodiments of the present invention are used to selectively control power to regions of a semiconductor device. By removing power from a region of a device that is inactive, the semiconductor device, among other advantages, drains less power, resulting in longer battery life, and reduces heat generated. The reduced power allows systems using these devices to have smaller batteries or other power sources. And because regions of a semiconductor device disconnected from a power source are not generating heat, they can be spaced closer together, thereby reducing chip size and allowing for smaller device geometries and thus product footprints. Reducing heat also allows for smaller heat sinks and reduces the risk of devices malfunctioning or failing.

In accordance with the present invention, a semiconductor device has separate functional modules and power is separately controlled to each. If it is determined that a functional module is “inactive,” then power to that functional module is reduced, possibly to zero. When it is determined that the functional module is needed to perform a task, power to it is restored. The invention is thus directed to architectures of a semiconductor device that conserve power, processes carried out on the devices to conserve power, and processes to fabricate these devices.

Embodiments of the present invention add power circuitry to a semiconductor device, so that the power control circuitry forms part of the semiconductor device. These embodiments differ from structures in which circuitry is merely added to or is external to an already existing semiconductor device or system. Because they form part of the semiconductor device circuitry, power control circuitry of the present invention can be optimized during the design and fabrication process to suit the underlying semiconductor device electronics by, for example, reducing the number of electronic components, reducing the number of strategic points that must be monitored to determine when to reduce power, to name only a few design elements that can be optimized. These design elements can also be selected to improve the manufacturability of the semiconductor device.

In accordance with the present invention, power consumption is reduced by applying dynamic clock gating, in which clocks are turned on and off based on the behavior of signals. The consumption of static power (e.g., leakage) is reduced by dynamically turning on and off header transistors, footer transistors, power islands, or other power blocks to a functional module.

As used herein, “functional modules” are any modules designed to perform tasks, interdependent or not. They include multiprocessors for executing multiple threads of a single process, floating point and other arithmetic units, graphics modules, digital signal processing elements, or any other “active” circuitry that requires power. Preferably, the functional modules are all fabricated on a single semiconductor die.

While many of the examples that follow show a system with only a few functional modules, it will be appreciated that the present invention is able to be used with systems that have many more functional modules.

Determining when Power can be Removed from a Functional Module

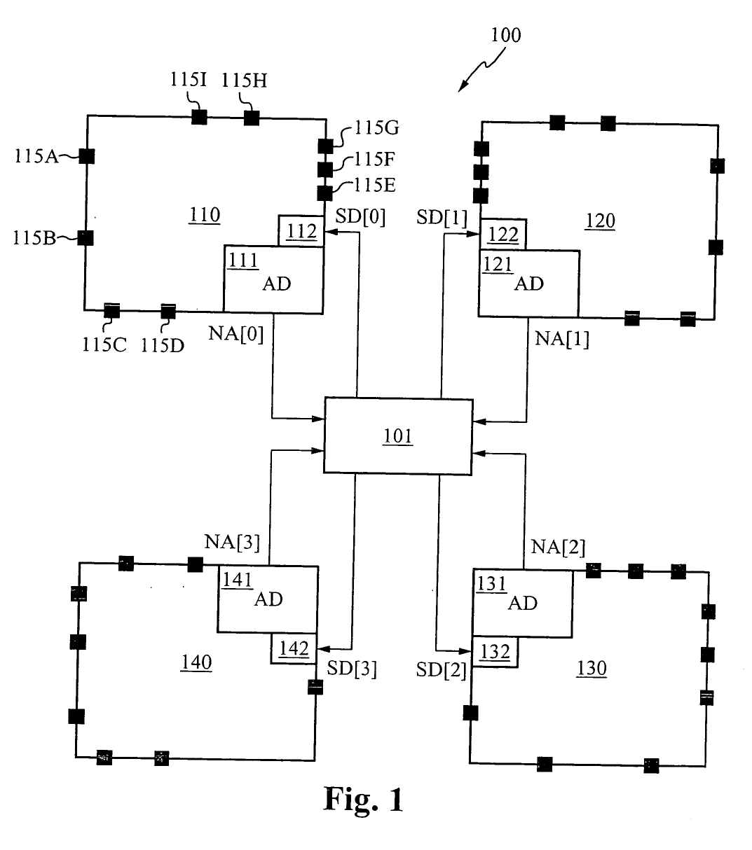

FIG. 1 shows the basic components of a semiconductor device 100 in accordance with the present invention. The device 100 includes functional modules 110, 120, 130, and 140. As one example, the functional module 110 is a graphics processor for generating a portion of a graphics element. The functional module 110 offloads some of its processing to the functional module 120, here an arithmetic unit 120. The functional module 110 is thus able to be shut down while waiting for processed data from the functional module 120, thereby conserving power. In this example, the functional module 110 is dependent on the functional module 120, receiving processed data from it. In other examples, the functional module 110 operates independently of the functional module 120.

It has been recognized that data is generally processed within a functional module—and thus the functional module must remain energized—for a minimum duration after the data has been input into the functional module. As one example, if data is input into the functional module at time t₀ and it takes until time t₅ to process the data within the functional module before outputting it, then the functional module must remain energized at least until time t₅. This is true even if no other data is input into the functional module between time t₀ and time t₅. This duration may be determined from a depth of a deepest processing pipeline within the functional module, from a number of iterations of a processing loop within the functional module, or from some other structure or algorithm performed within the functional module.

Thus, to properly determine whether activity is occurring within a functional module, an element that detects signals input into a functional module (called an “activity detector”) must wait a “wait time” equal to the largest of (a) a depth of the deepest processing pipeline within the functional module, (b) a length of time corresponding to the number of iterations in a processing loop, or (c) some other predetermined time, usually calculated in clock cycles. If no activity is detected during this wait time (e.g., no data is input to the functional module or no activities are occurring within a processing loop on the functional module), it is determined that no activity is occurring within a functional module, which can then be de-energized, thereby reducing power consumed and heat generated.

Any one of these predetermined times is able to be selected as the wait time to fit the application at hand or to simplify the circuitry of the resulting system. Preferably, the wait time is the depth of the longest processing pipeline within a functional module.

In accordance with the present invention, a depth of a processing loop is determined by “cutting” the loop and extending it to a length corresponding to the number of iterations performed in the processing loop. The processing loop within a functional module is thus functionally equivalent to a pipeline. Accordingly, the length of the processing loop corresponds to and is thus also referred to as a pipeline depth. All references below to a pipeline depth, thus refer to the depth of stages within a pipeline or the length of a processing loop.

In the embodiments described below, activity is detected using an activity detector, and power or energy to a functional module is controlled, such as by reducing voltage or current or reapplying the voltage or current, using an “energy controller.” Generally, the activity detector monitors activity on an input line to a functional module or on a negative loop within the functional module; that is, a loop that uses feedback to move a system to an “equilibrium” state, such as by maintaining a signal on the loop at a specific value or by performing iterations until the signal converges to the specific value. These input lines are referred to as “strategic points.” After reading this Specification, those skilled in the art will recognize that activity can be monitored at strategic points other than input lines.

### Specific Embodiments

FIG. 1 shows a portion of a semiconductor device 100 having an energy controller 101 coupled to functional modules 110, 120, 130, and 140. The functional modules 110, 120, 130, and 140 include activity detectors 111, 121, 131, and 141, respectively. The functional modules 110, 120, 130, and 140 also include power control blocks 112, 122, 132, and 142, respectively. The functional module 110 contains input ports 115A-I, considered strategic points because signals on these ports are monitored.

As described in more detail below, the exemplary activity detector 111 detects activity on the functional module 110, at strategic points on the functional module 110. When the activity detector 111 determines that there has been no activity on (e.g., no input signals into) the functional module 10 for a wait time (described above), it generates a first signal on the line NA[0] (“No Activity”), which is transmitted to the energy controller 101. When the energy controller 101 receives the first signal, it generates a second signal on the line SD[0] (“Shut Down”) after waiting a number of cycles equal to a pipeline depth, which is transmitted to the power control block 112. In response to the second signal, the power control block 112 reduces power to the functional circuitry (e.g., the elements besides the activity detector 111 and the power control block 112) of the functional module 101 or turns off the clock to the functional circuitry, or reduces power to the functional circuitry using other means, such as by using bus or gate biasing means.

As used herein, the term “functional circuitry” refers to circuitry used to perform the underlying function (e.g., generating graphics data or calculating arithmetic data) of a functional module. The term “power control circuitry” refers to circuitry used to control power in accordance with the present invention. It will be appreciated that some components can be part of both functional circuitry and also power control circuitry.

Continuing the example in FIG. 1, when the activity detector 111 detects activity on the functional module 110 or otherwise determines that activity is needed to be performed on the functional module 110, the activity detector 111 generates a third signal on the line NA[0]. When the energy controller 101 receives the third signal, it generates a fourth signal on the line SD[0], which is transmitted to the power control block 112. When the power control block 112 receives the fourth signal, it restores power to the functional circuitry of the functional module 110.

The first, second, third, and fourth signals are able to be any combination of logic LOW and logic HIGH signals. As used herein, the term “a signal” refers to a logic HIGH signal and the term “no signal” refers to a logic LOW signal. This selection is arbitrary, used merely for illustration. Other embodiments of the invention use the term “a signal” to refer to a logic LOW signal and “no signal” to refer to a logic HIGH signal.

In a preferred embodiment, each of the first, second, third, and fourth signals is either a logic LOW signal (e.g., 0 volts) or a logic high signal (e.g., 0.7 volts). In this preferred embodiment, each of the first, second, third, and fourth signals is thus any one of two signals. Those skilled in the art will recognize, however, that each of the first, second, third, and fourth signals can be signals having one of any number of values. For example, the first, second, third, and fourth signals can all have different values that depend on the type of transistors used to fabricate the individual components of the semiconductor device 100.

The energy controller 101 similarly controls power to the functional modules 120, 130, and 140. Because it centrally controls power to multiple functional modules, the energy controller 101 is able to coordinate power to the functional modules 110, 120, 130, and 140. Thus, as explained in the description of FIG. 9, if the functional module 120 generates data to be used on the functional module 110, the energy controller 101 is able to power ON the functional module 110 so that it is ready to process the data as soon as the data is available, without any delays. The system 100 is thus able to “look ahead” to power ON circuitry downstream of a signal or data path, based on signals upstream in the data path.

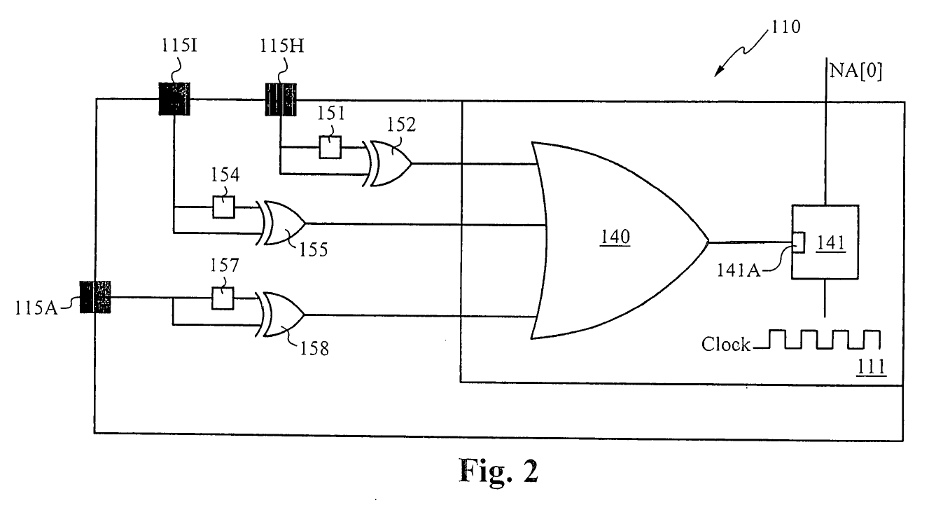

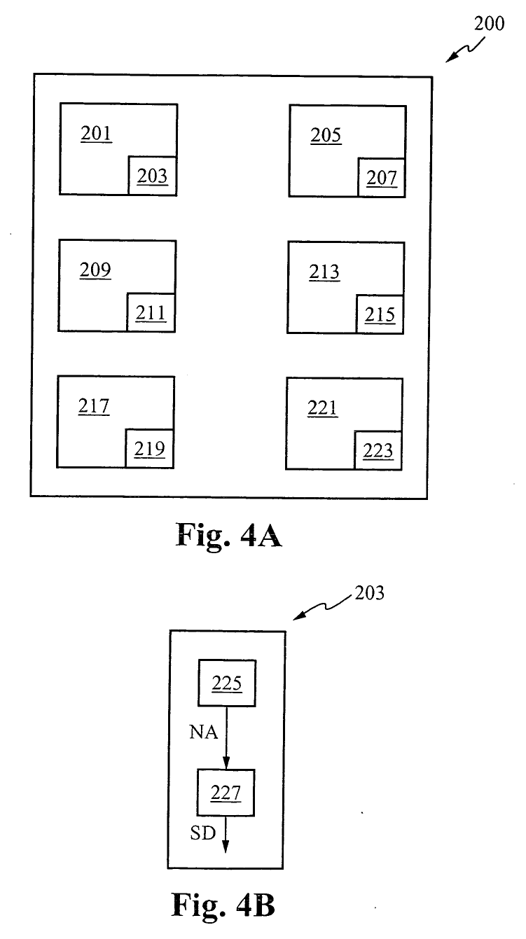

FIG. 2 is a more detailed illustration of several components of the functional module 110 of FIG. 1. FIG. 2 shows components of a semiconductor device (100, FIG. 1) that has a single “centralized” energy controller, used to control power to multiple functional modules. FIG. 4 shows a system that uses “localized” energy controllers in accordance with embodiments of the present invention, each of which is dedicated to, and thus controls power to, a single functional module. FIG. 2 is used to show (1) how strategic points are monitored and (2) how to determine that a wait time has elapsed to thereby (3) generate a signal indicating that a functional module can be de-energized. Throughout this description, identically labeled components refer to the same component.

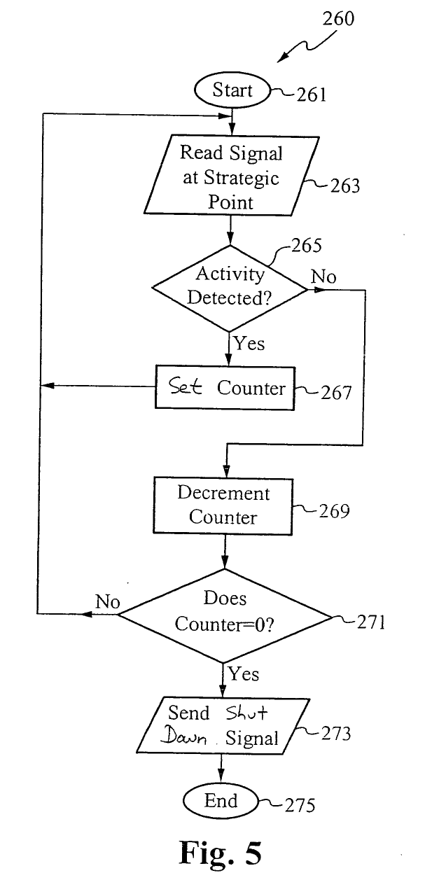

As shown in FIG. 2, the activity detector 111 includes a multi-input OR gate 140. The OR gate 140 has inputs coupled to inputs 115A-I (though only inputs 115A, 115H, and 115I are shown, to simplify FIG. 2). It will be appreciated that the activity detector 111 is also able to be coupled to negative loops (not shown) within the functional module 110. The inputs to the OR gate 140 are coupled to the outputs of the XOR gates 152, 155, and 158. The XOR gate 152 has a first input directly coupled to the input 115H and a second input coupled to the input 115H by a D flip flop 151. The XOR gate 155 has a first input directly coupled to the input 115I and a second input coupled to the input 115I by a D flip flop 154. The XOR gate 158 has a first input directly coupled to the input 115A and a second input coupled to the input 115A by a D flip flop 157. The output of the XOR gates 152, 155, and 158 is thus HIGH only if the signal at the inputs 115H, 115I, and 115A, respectively, (strategic points) changes between clock cycles. The output of the OR gate 140 is coupled to a Set line 141A of a counter 141. The counter 141 is preferably hardwired, but could be otherwise programmed, to output a logic HIGH on the line NA[0] after a number of clock cycles equal to the predetermined wait time for (e.g., the depth of the deepest pipeline within) the functional module 110. In other words, if no input changes are detected at any of the strategic points (115A-I), a logic HIGH is generated on the line NA[0], indicating the functional module 110 is inactive and is able to be powered down. Preferably, the counter 141 counts down, such as described in FIG. 5, but the counter 141 can also be configured to count up.

If any input is detected on any of the strategic points, the output of the OR gate 140 sets the counter 141 (such as to a value of the maximum pipeline depth), so that a new wait cycle is started. Also, when the counter 141 is set, a logic LOW is generated on the line NA[0], indicating that the functional module 110 is active and its functional circuitry must be powered on. The energy controller 101 receives this LOW signal on the line NA[0] and generates a logic LOW on the line SD[0], controlling the power control block 112 to energize the functional module 110.

It will be appreciated that while FIG. 2 shows the counter 141 on the activity detector 111, the counter 141 is also able to be located on the energy controller 101 or on some other component. Those skilled in the art will recognize different configurations in which components are packaged differently in accordance with the present invention, such as using multi-chip packages or different chips on a system.

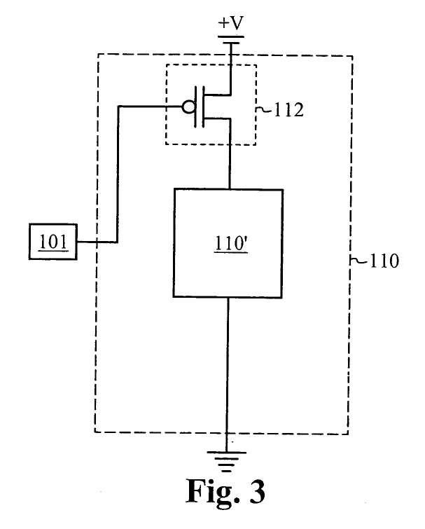

Once an activity detector determines that a functional module is inactive and sends a signal to an energy controller, the energy controller is able to reduce power to the functional module. FIG. 3 shows circuitry for reducing (here, removing) power to the functional module 110 in accordance with the present invention.

FIG. 3 shows the energy controller 101 of FIG. 1 coupled to the functional module 110. The functional module includes a transistor 112 and the functional circuitry 110′ of the functional module 110. The transistor 112 forms part of the power control block 112 of FIG. 1. The energy controller 101 is coupled to the transistor 112. The transistor 112, referred to as a “header transistor,” electrically couples a power source +V to the functional circuitry 110′. Thus, when the energy controller 101 turns off the header transistor 112, it disconnects the power source from the functional circuitry 110′, conserving power. When the energy controller 101 turns on the header transistor 112, it connects the power source to the functional circuitry 110′.

In other embodiments, the header transistor 112 is replaced with a “footer transistor” (not shown) that couples an output of the functional circuitry 110′ to ground. The footer transistor is also controlled (turned on and off) by the energy controller 101. Still other embodiments use both header and footer transistors.

FIG. 4A is a block diagram of a system 200 in accordance with the present invention, in which multiple functional modules or regions 201, 205, 209, 213, 217, and 221 each has its own dedicated energy management module 203, 207, 211, 215, 219, and 223, respectively. The exemplary energy management module 203 controls power to the functional module 201 based on activity on the functional module 201. In one embodiment, the energy management module 203 reduces or removes power to the functional module 201 when it detects no activity on the functional module 201 and applies power to the functional module 201 when it detects activity on the functional module 201. The energy management module reduces or removes power, such as by turning on and off transistors that couple the functional module 201 to a power source, by using clock gating, by using back bias or power islands or gate biasing, or by using other means known to those skilled in the art.

FIG. 4B is a block diagram of the exemplary energy management module 203. The energy management module 203 includes an activity detector 225 coupled to an energy controller 227. A signal NA (“No Activity”, with values that can be denoted by indexes, such as [0] and [1], used in the examples above) is generated on the output of the activity detector 225, and a signal SD (“Shut Down”, with values that can be also denoted by indexes, such as [0] and [1]) is generated on the output of the energy controller 227. The signals NA and SD have the same meanings throughout this Specification.

FIG. 5 is a flowchart showing steps 260 of a process for determining whether activity is occurring within a functional module and thus whether power is to be disconnected from the functional module. Referring to FIG. 5, in the start step 261, any variables, such as a count variable (e.g., a hardware counter, such as element 141 in FIG. 2) and a wait time (e.g., a pipeline depth), are initialized. For example, the counter is set to a maximum pipeline depth, such as described above. Next, in the step 263, a signal at a strategic point is read, and in the step 265, the process determines whether the signal indicates activity. If the signal indicates activity (e.g., the signal is a logic HIGH), then the process continues to the step 267, in which the counter is set to the maximum pipeline depth, and loops back to the step 263. If the signal indicates no activity (e.g., a logic LOW), the process continues to the step 269, in which the counter is decremented.

Next, the process continues to the step 271, in which it is determined whether the counter equals 0. If the counter does not equal 0, then the process loops back to the step 263; otherwise, the process continues to the step 273. In the step 273, the process ultimately generates and sends a shut down signal. This is performed, for example, by an activity detector generating a HIGH signal on the line NA[0] and an energy controller responding by generating a HIGH signal on the line SD[0], both as shown in FIG. 1. As explained above, power can be reduced or otherwise controlled to a functional module or region by using clock gating, using header or footer transistors to disconnect power, using back bias or gate biasing, or using any other means recognized by those skilled in the art. The process then ends in the step 275. The functional module is now de-energized.

As described below, a functional module is later re-energized when it is determined that it must perform a function.

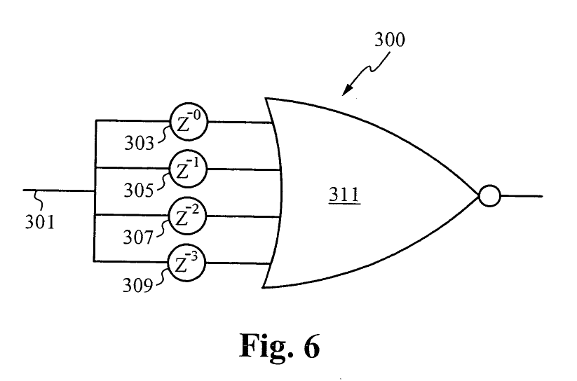

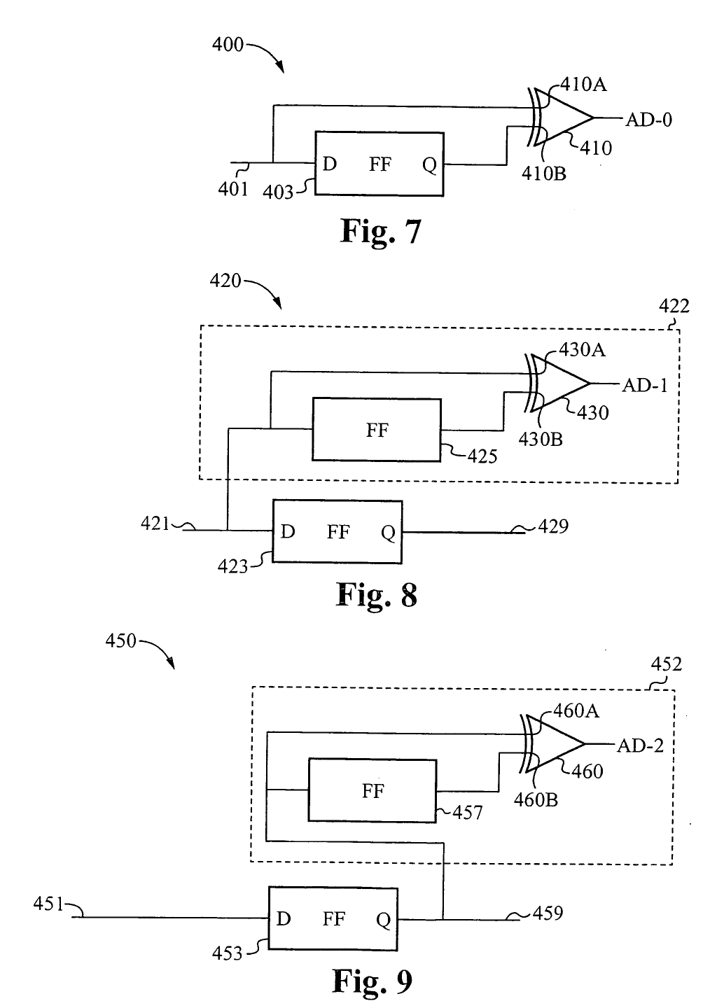

FIG. 6 is a block diagram used to logically illustrate circuitry 300 for determining whether activity is detected on a functional module during successive clock cycles and thus whether a functional module is able to be powered down. The circuitry 300 helps to explain the embodiments of activity detectors in FIGS. 7-9.

The circuitry 300 includes a four-input NOR gate 311, which generates a logic HIGH only if all of its inputs are LOW. A signal line 301 is coupled to a strategic point (not shown) and also to multiple delay components 303, 305, 307, and 309, all of which have outputs coupled to the inputs of the NOR gate 311. The delay component 303 is labeled z⁻⁰ to indicate that it holds the signal on the line 301 for the current clock cycle. The delay component 305 is labeled z⁻¹ to indicate that it holds the signal on the line 301 for the previous clock cycle (a “delay” of 1); the delay component 307 is labeled z⁻² to indicate that it holds the signal on the line 301 for the previous clock cycle (a delay of 2); and the delay component 309 is labeled Z⁻³ to indicate that it holds the signal on the line 156 for the previous clock cycle (a delay of 3). Thus, the inputs to the NOR gate 311 are all LOW and its output is HIGH only if there has been no activity on the signal line 301 for the wait time of four successive clock cycles.

FIGS. 7-9 show three activity detectors 400, 420, and 450, respectively, in accordance with three embodiments of the present invention. The activity detector 400 in FIG. 7 is used for relatively slow circuitry. The activity detector 400 includes a line 401 for monitoring a strategic point for any changes in activity. The monitored line 401 is coupled to an input of a D flip flop 403 and to a first input 410A of an XOR gate 410. The D flip flop 403 has an output that is coupled to a second input 410B of the XOR gate 410. Thus, in operation, the signal on the monitored line 410A corresponds to a signal at the strategic point during the current clock cycle and the signal on the line 410B corresponds to a signal at the strategic point on the previous clock cycle. The output AD-0 from the XOR gate 410 is thus HIGH only if the two signals are LOW; that is, if there is no activity at the strategic point during the last two clock cycles.

In other embodiments, the activity detector 400 (as well as the activity detectors 420 and 450 discussed below) generates a logic LOW signal if no activity is detected at monitored strategic points and a logic HIGH signal if activity is detected. In these other embodiments, an energy controller coupled to the activity detector is programmed to receive the LOW signal from the activity detector 400 and, in response to the LOW signal, generate signals used to de-energize a functional module.

Referring to FIG. 6, and modifying it slightly to delete the elements 307 and 309, the signal on the line 410A corresponds to the output from the element 303 (the signal on an input line during the current clock cycle) and the signal on the line 410B corresponds to the output from the element 183 (the signal on the same line from the previous clock cycle).

The circuitry 420 in FIG. 8 includes a monitored input line 421 coupled to both an input of an existing D flip flop 423 and an input of an activity detector 422. The activity detector 422 includes an input that is coupled to an input of a flip flop 425 and to a first input 430A of an XOR gate 430. The output of the flip flop 425 is coupled to a second input 430B of the OR gate 430. The output of the XOR gate 430 AD-1 is HIGH only when there has been no activity or change on the monitored line 421 for a clock cycle.

In some cases, the existing flip flop 423 is included in the circuitry 420 because the circuitry includes fast clock cycles: the flip flop 423 decreases the time that a signal is gated on the line 429 to other circuitry, thereby allowing the other circuitry time to set up to receive the gated signal. Thus, the activity detector 422 is used on systems with clock cycles faster than clock cycles that drive systems using the activity detector 400.

The flip flop 423 is said to be “existing” because it forms part of the functional circuitry, as described above. The flip flop 423 is thus part of the circuitry existing before the activity detector 422 is added in accordance with the present invention. Adding the activity detector 422 in parallel to an existing flip flop 423 exploits the flip flop 423 (making use of an existing one rather than requiring the addition of one), simplifying the design of the circuitry 420.

FIG. 9 shows circuitry 450 used to monitor signals having clock cycles even faster than the circuitry 420 shown in FIG. 8. The circuitry 450 includes a monitored input line 451 coupled to an input of an existing D flip flop 453, which has an output line 459. An output of the D flip flop 453 is coupled to an input of an activity detector 451, which includes a flip flop 457 and an XOR gate 460. The output line 459 is coupled to an input to the flip flop 457 and to a first input 460A of the XOR gate 460. The output of the flip flop 457 is coupled to a second input 460B of the XOR gate 460. The output of the XOR gate 460 AD-2 is HIGH when no activity is detected on the monitored line 451 for two successive clock cycles.

While FIGS. 7-9 show activity detectors used for circuitry having different speeds, after reading this Specification those skilled in the art will recognize other structures for activity detectors, customized for speed of circuitry, optimal device dimensions, spacing of heat-generating components, and the like.

The layout and design of the circuitry is able to be customized in many ways in accordance with the present invention. As one example, device components are grouped so that devices that are seldom on (seldom-ON or “low duty cycle” devices) are grouped together, sharing one or more power sources; and devices that are often on (often-ON or “high duty cycle” devices) are grouped together, sharing one or more power sources. In this way, seldom-ON devices are not kept energized unnecessarily because they are grouped with often-ON devices that often need power.

As described in more detail below, a functional modules is also able to be divided into separate “regions” that can be separately turned ON and OFF in accordance with the present invention.

The optimization step is customized so that other factors are taken into account when determining a device layout. This includes the grouping of components based on their duty cycles or pipeline depth; decreasing the number of strategic points that must be monitored; decreasing the trace line distances between components and between components and power sources; spacing components so as to reduce the heat-inducing effects between them; reducing the relations between regions, thereby allowing regions to be shut down independently of others; minimizing the depth of regions so that they can be shut down quickly; minimizing the number of flip flop drivers, thereby reducing the number of gates in the system; to name a few optimization parameters. These factors, and others, are taken into account; some factors are weighted more than others, depending on the specific design at hand.

Preferably, a functional module also includes an input frame: that part of a functional module that must remain energized and is thus used to monitor inputs into the functional module. Thus, while the functional circuitry is able to be de-energized to conserve power, the relatively small input frame remains energized. In one embodiment, the input frame includes a flip flop directly coupled to an input of a functional module. Those skilled in the art will recognize that an input frame is able to have many different structures. Optimal designs reduce the number of discrete components that form the input frame, thereby reducing the number of components of a functional module that must remain energized, even in a power down or de-energized mode.

In other embodiments, a first functional module is coupled to other functional modules. Unlike the embodiment above, in which components of a frame always remain energized, the first functional module in these other embodiments contain components, such as flip flops, that are energized only when activity is detected on the other functional modules.

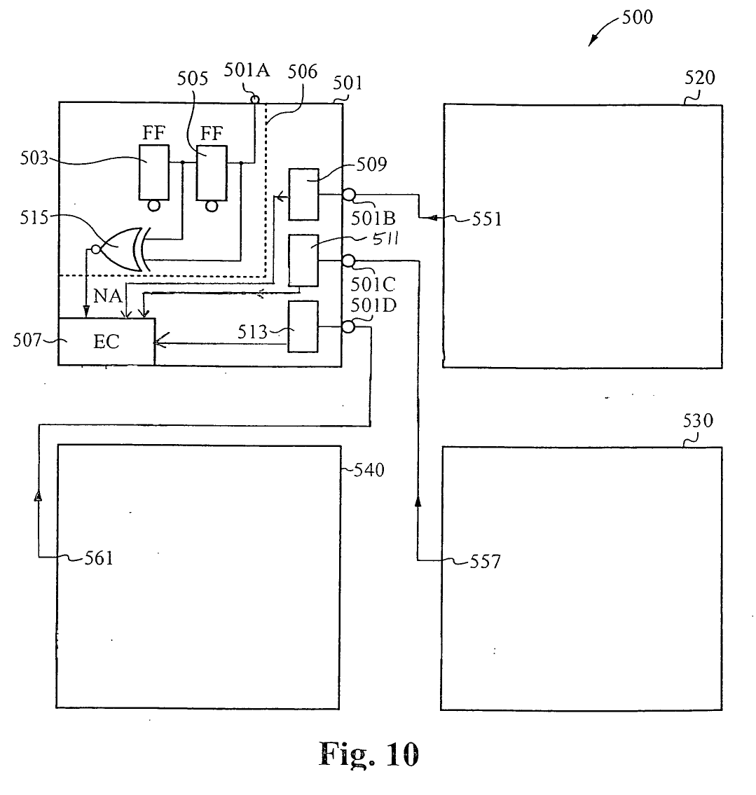

FIG. 10 shows a system 500 in which a functional module 501 is coupled to three other functional modules 520, 530, and 540. Preferably, all the functional modules 501, 520, 530, and 540 are all formed on a single semiconductor die. The functional modules 520, 530, and 540, all generate outputs that are transmitted to the functional module 501. The system 500 also illustrates a configuration in which an energy controller resides on a single functional module rather than at a central location for controlling multiple functional modules, as shown in FIG. 1.

The functional module 501 has inputs 501A-D and includes D flip flops 503 and 505, an XOR gate 515, electronic components 509, 511, and 513, and an energy controller 507. The input 501A (a strategic point) is coupled to an input of the flip flop 505 and also to a first input of the XOR gate 515. An output of the flip flop 505 is coupled to a second input of the XOR gate 515 and also to an input of the flip flop 503. The output NA of the XOR gate 515 is coupled to an input of the energy controller 507. The output NA is HIGH when no activity is detected at the strategic point 501A during two successive clock cycles. The flip flops 503 and 505 and the XOR gate 515 together form an input frame 506.

An output 551 from the functional module 520 is gated to the input 501B, which in turn is coupled to an input of the electronic component 509; an output 557 from the functional module 530 is gated to the input 501C, which in turn is coupled to an input of the electronic component 511; and an output 561 from the functional module 540 is gated to the input 501D, which in turn is coupled to an input of the electronic component 513. Outputs of the electronic components 509, 511, and 513 are all coupled to, and thus monitored by, the energy controller 507.

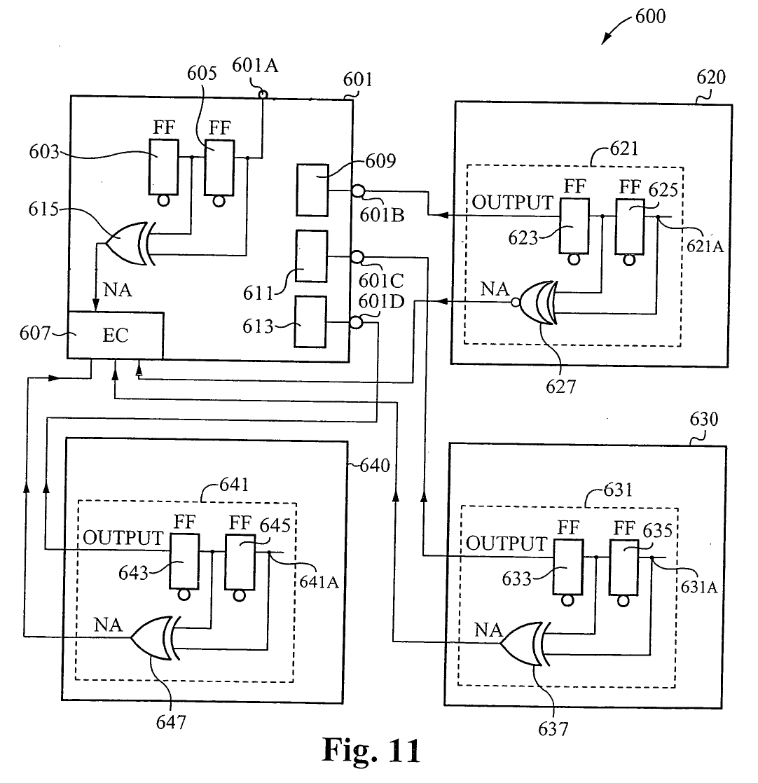

In the embodiment of FIG. 10, the electronic components 509, 511, and 513 are always ON, ready to receive and process data (e.g., signals) on the inputs 501B, 501C, and 501D. As explained below, in the embodiment shown in FIG. 11, corresponding electronic components 609, 611 and 613 do not have to be continuously ON, but can be OFF, energized only when signals are about to be transmitted to the corresponding inputs 601B, 601C, and 601D, thereby conserving power.

FIG. 11 illustrates a system 600 in which, as in the system 500, a functional module receives data from, and is thus interdependent with, other functional modules. The system 600 is configured so that one functional module is powered ON before the data is ready to be sent from another functional module, thereby ensuring that there is no delay powering ON the one functional module when the data is ready: The one functional module is ready to receive and process the data as soon as the data is ready. The system 600 also illustrates a configuration in which an energy controller resides on a functional module rather than at a central location for controlling multiple functional modules, as shown in FIG. 1.

Referring to FIG. 11, the system 600 includes three functional modules 620, 630, and 640, all generating outputs that are transmitted to a fourth functional module 601. FIG. 11 thus illustrates how an energy controller 607 on the functional module 601 monitors signals generated within the functional module 601 and also monitors outputs from the functional modules 620, 630, and 640 to energize electrical components 609, 611, and 613 on the functional module 601, as well as other components on the functional module 601, in accordance with the present invention.

The functional module 601 has inputs 601A-D. The input 601A (a strategic point) is coupled to an input of a flip flop 605 and also to a first input of the XOR gate 615. An output of the flip flop 605 is coupled to a second input of the XOR gate 615 and also to an input of a flip flop 603. The output NA of the XOR gate 615 is coupled to an input of the energy controller 607. The output NA is HIGH when no activity is detected at the strategic point 601A during two successive clock cycles.

The functional module 620 contains a signal line 621A (a strategic point) coupled to an input of a flip flop 325 and also to a first input of an XOR gate 627. The output of the flip flop 625 is coupled to an input of a flip flop 623 and also to a second input of the XOR gate 627. The output of the flip flop 623 is coupled to the input 601B of the functional module 601. The input 601B is coupled to the electronic component 609 on the functional module 601. The output NA of the XOR gate 627 is coupled to an input of the energy controller 607.

Looked at another way, the functional module 620 contains a signal path that includes a first stage and a second stage. The first (or intermediate) stage is defined by the flip flop 625 and a signal line that couples the flip flop 625 to the flip flop 623. The second (or output) stage is defined by the flip flop 623 and a signal line that directly couples the flip flop 623 to the input 601B. As defined herein, a “stage” includes a signal line and circuitry that computes a function, such as by using a flip flop or any other delaying circuitry. As explained below, monitoring a signal on an intermediate stage of the functional module 620 allows the system to look ahead and thereby energize the functional module 601 before a signal reaches an output stage of the functional module 620. It will be appreciated that embodiments of the present invention are able to “look ahead” any number of clock cycles by monitoring the outputs from earlier stages in a data or signal path.

The functional module 630 contains a signal line 631A (a strategic point) coupled to an input of a flip flop 635 and also to a first input of an XOR gate 637. The output of the flip flop 635 is coupled to an input of a flip flop 633 and also to a second input of the XOR gate 637. The output of the flip flop 633 is coupled to the input 601C of the functional module 601. The input 601C is coupled to the electronic component 611 on the functional module 601. The output NA of the XOR gate 637 is coupled to an input of the energy controller 607.

The functional module 640 contains a signal line 641A (a strategic point) coupled to an input of a flip flop 645 and also to a first input of an XOR gate 647. The output of the flip flop 645 is coupled to an input of a flip flop 643 and also to a second input of the XOR gate 647. The output of the flip flop 643 is coupled to the input 601D of the functional module 601. The input 601D is coupled to the electronic component 613 on the functional module 601. The output NA of the XOR gate 647 is coupled to an input of the energy controller 607.

In operation, because the output from the exemplary flip flop 623 is one clock signal behind the input to the XOR gate 627, which is routed to the energy controller 607, the functional module 601 is energized before the output from the flip flop 623 reaches the input 601B. Thus, the functional module 601 is energized and ready to process data (in the form of signals) on the line 601B before the data arrives. Those skilled in the art will recognize other circuitry for “looking ahead” and re-energizing a functional module any number of clock cycles before the data arrives at the functional module.

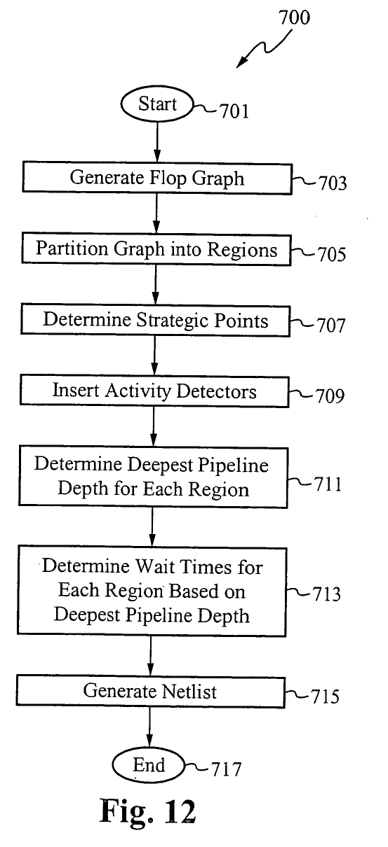

FIG. 12 is a flow chart illustrating the steps of a process 700 for modeling circuitry that includes activity detectors and energy controllers in accordance with the present invention. The process begins with the start step 701, in which data structures and other variables are initialized. Next, in the step 703, a flop graph for the basic circuitry is generated. Next, in the step 705, the flop graph is partitioned into regions and in the step 707, strategic points are determined for monitoring signals indicating activity. A region can include an entire functional module, portions of a functional module, functional circuitry, an input frame, and the like. Next, in the step 709, activity detectors are inserted. Next, in the step 711, the deepest pipeline depth is determined for each region. As explained above, pipeline depths are also determined for iteration loops, which are treated as the functional equivalent of pipelines. In the step 713, a wait time for each region is determined from the depth of its deepest pipeline. Next, in the step, 715, a corresponding netlist is generated. Finally, the process ends in the end step 717. A semiconductor device is then fabricated using the netlist.

While FIG. 12 shows a specific sequence of steps, those skilled in the art will recognize that the present invention can be practiced by changing the order of some of the steps, substituting other steps for those shown, or even by eliminating some of the steps.

Those skilled in the art will also recognize that in one embodiment, the steps of the process 700 are performed multiple times, using different configurable optimization parameters, to determine an optimal device to fit the application at hand. As one example, the application requires that heat-generating devices be separated by a specific amount and that the number of regions be minimized. These requirements are included in the fabrication rules used to generate the netlist. Several netlists are generated, with the one that satisfies both parameters selected to fabricate the device. It will be appreciated that other fabrication rules, weighing different optimization parameters, are also able to be used in accordance with the present invention.

Embodiments of the present invention thus include software and hardware components. The software components, such as described below, include components that perform one or more of the following functions: partitioning portions of a semiconductor device, such as by determining which portions can be turned ON or OFF together and thus can be controlled by a single energy controller. In one embodiment, optimization includes, as first steps, determining processing loops on a functional module and “cutting” the processing loops to determine the depth of the corresponding pipeline. Optimization continues by minimizing any one or more of (a) the number of strategic points (e.g., inputs and points on any processing loops within a functional module) that must be monitored, (b) the number of processing loops, (c) the number of portions that the semiconductor device is partitioned into, and (d) the maximum pipeline depth of a partitioned region, to name a few optimization steps. Minimizing the maximum pipeline depth allows the system to more quickly reduce, shut down, or otherwise control power to a region, thereby reducing the overall power consumed by the system.

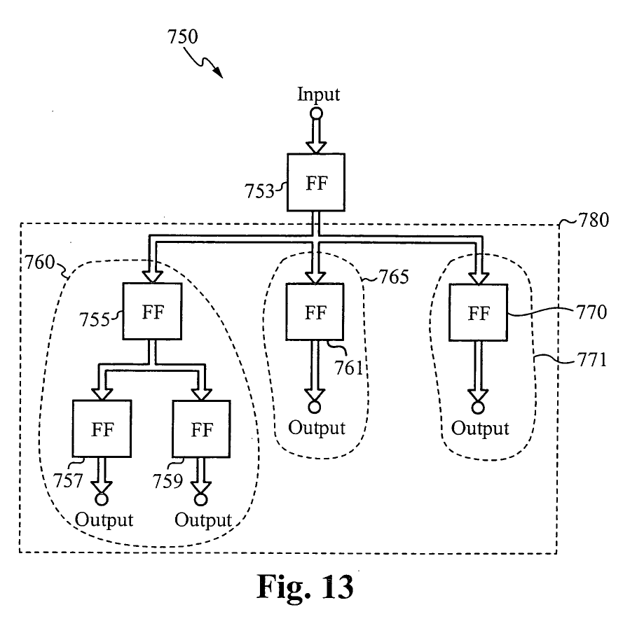

FIG. 13 shows a flop graph 750 generated as a step in generating a netlist in accordance with the present invention. The term “flop graph” refers to a graph with each node corresponding to a flip flop in the integrated circuit design. The flop graph 750 includes a flip flop 753 coupled to a region 780. The region 780 includes a first branch 760, a second branch 765, and a third branch 771. The first branch 760 contains a root flip flop 755 coupled to a first sub-branch containing a leaf flip flop 757 and a second sub-branch containing a leaf flip flop 759. The second branch 765 contains the single (root and leaf) flip flop 761, and the third branch 771 contains the single (root and leaf) flip flop 770. The outputs of the flip flops 757, 759, 765, and 770 are each outputs for the region 780.

In operation, the region 780 is configured so as to optimize a configurable parameter, as discussed above. It will be appreciated that the branch 760, contains a first pipeline formed by the flip flops 755 and 757, which combined have a depth of two (two flip flops), and a second pipeline formed by the flip flops 755 and 759, which combined have a depth of two. The branch 765 contains a pipeline formed by the flip flop 761, which has a depth of one. The branch 771 contains a pipeline formed by the flip flop 770, which has a depth of one. The deepest pipeline within the region 780 thus has a length of 2. The counter in the algorithm shown in FIG. 5, will thus be set to 2.

Embodiments of the present invention reduce power consumption on semiconductor chips that use multiple functional modules. In operation, activity is monitored on a functional module. If it determined that activity has not occurred for a predetermined number of clock cycles (a wait time), power is reduced to the functional module. Later, when a signal is detected on an input to the functional module, the functional module or one that receives input from the functional module is turned on.

During the fabrication of a semiconductor device of the present invention, the functional modules are able to be partitioned into regions according to configurations using any number of optimization parameters. Configurations include, but are not limited to, those that minimize (1) relations between regions, (2) pipeline depths, (3) the number of components such as flip flops, (4) the number of regions, (5) the number of strategic points, and (6) the number of processing loops, to name a few.

In one embodiment, when a system containing functional modules is first powered on, a selected subset of the functional modules are left de-energized. Only when a functional module is needed to perform a task is it energized. Thus, little-used functional modules are not unnecessarily powered on at start up, only to be de-energized later, without having performed any functions.

It will be appreciated that signals discussed in the embodiments of this invention are able to be interpreted in many ways. As one example, an activity detector is programmed to generate a selected one of a signal LOW and a signal HIGH as indicating no activity at a strategic point. An energy controller coupled to the activity detector is programmed to recognize the selected signal (e.g., LOW) as indicating no activity at the strategic point and the other signal (e.g., HIGH) as indicating activity. When the energy controller receives the selected signal (e.g., LOW), it generates a signal used to reduce power to a functional module in accordance with the present invention; when the energy controller receives the other signal (e.g., HIGH), it generates a signal used to apply power to the functional module.

Similarly, in other examples discussed above, active HIGH components can be substituted for active low components and vice-versa. Thus, the selection and interpretation of signals is arbitrary, so long as it achieves the invention.

It will also be appreciated that in accordance with the present invention, activities are able to be monitored for any number of reasons. As merely one example, activity on functional modules are monitored to balance loads: when it is determined that one functional module is active but another is inactive, the inactive one is selected to perform a task. Those skilled in the art will recognize many other applications that used monitored signals to perform tasks other than controlling power to functional modules.

It will be readily apparent to one skilled in the art that many other modifications may be made to the embodiments without departing from the spirit and scope of the invention as defined by the appended claims.

I claim:

1. A system for controlling power to one or more functional modules or regions of a semiconductor device comprising:
a. a first functional module from the one or more functional modules, wherein the first functional module contains a first activity detector; and
b. an energy controller coupled to the first activity detector and programmed to control power to the first functional module based on an output from the first activity detector.

2. The system of claim 1, wherein the first activity detector is coupled to one or more strategic points on the first functional module.

3. The system of claim 2, wherein the one or more strategic points comprise an input to the first functional module.

4. The system of claim 1, wherein the energy controller is programmed to wait a predetermined number of successive clock cycles before reducing power or gating a clock to the first functional module.

5. The system of claim 4, wherein the predetermined number of clock cycles correspond to a longest depth of a pipeline on the first functional module.

6. The system of claim 2, wherein the first activity detector is programmed to signal the energy controller to restore power to the first functional module when the first activity detector detects activity at any of the one or more strategic points.

7. The system of claim 1, further comprising a second functional module from the one or more functional modules.

8. The system of claim 7, wherein the second functional module contains a second activity detector coupled to the energy controller, and the energy controller is also programmed to control power to the second functional module based on an output from the second activity detector.

9. The system of claim 7, wherein the energy controller is also programmed to control power to the first functional module based on an output of the second activity detector.

10. The system of claim 7, wherein the first functional module, the second functional module, and the energy controller are formed on a single die.

11. The system of claim 7, wherein the first and second functional modules are two processors in a multiprocessor architecture.

12. The system of claim 1, wherein the first functional module is any one of an arithmetic module, a graphics module, and a digital signal processing module.

13. The system of claim 1, wherein the first functional module also comprises a power control block coupling a power source to the first functional module.

14. The system of claim 13, wherein the power control block comprises any one or more of a control clock gating module, a power island, a footer transistor, a header transistor, a back bias module, a gate bias module, a voltage reduction module, and a clock speed reduction module.

15. A method of controlling power to one or more functional modules on a semiconductor device comprising:
a. monitoring activity on a first functional module from the one or more functional modules;
b. determining that the first functional module has been inactive for a predetermined duration of time; and
c. reducing power to the first functional unit based on the inactivity for the predetermined duration of time.

16. The method of claim 15, wherein the duration corresponds to a depth of a pipeline on the first functional module.

17. The method of claim 15, further comprising applying power to the first functional module when activity is detected at a strategic point on the semiconductor device.

18. The method of claim 17, wherein the strategic point is located on the first functional module.

19. The method of claim 17, wherein the strategic point is located on a second functional module from the one or more functional modules.

20. The method of claim 19, wherein the first functional module and the second functional module are formed on a single die.

21. The method of claim 15, wherein the first functional module is any one of an arithmetic module, a graphics module, and a digital signal processing module.

22. A method of generating a model of a semiconductor device having multiple functional modules comprising:
a. generating a flop graph corresponding to multiple regions of the multiple functional modules of the semiconductor device;
b. determining strategic points for monitoring activities within the multiple regions;
c. inserting an energy control module for controlling power to each of the multiple regions based on the activity monitored at the strategic points; and
d. generating a netlist corresponding to the semiconductor device.

23. The method of claim 22, wherein the energy control module comprises an activity detector at each of the multiple regions coupled to a single energy controller, wherein each activity detector raises a signal when activity in a region from the multiple regions is detected and the energy controller controls power to a region from the multiple regions in response to the signal.

24. The method of claim 23, further comprising determining a wait time between detecting no activity and raising the signal, wherein the wait time corresponds to a pipeline length for a region from the multiple regions.

25. The method of claim 24, further comprising inserting a wait circuit for determining the wait time.

26. The method of claim 24, further comprising performing an optimization step for grouping the regions from the multiple regions based on an optimization parameter.

27. The method of claim 26, wherein the optimization parameter is based on one or more of a number of interdependencies between multiple regions, depths of pipelines within the multiple regions, and a number of drivers for electronic circuitry within the multiple regions.

28. The method of claim 27, wherein the optimization parameters are based on one or more of spacings between electronic components on the semiconductor device, distances between regions containing the electronic components, and distances between a power source and the multiple regions.

29. The method of claim 22, further comprising forming a semiconductor device corresponding to the netlist.

30. A system for controlling power to multiple functional modules comprising:
a first functional module from the multiple functional modules;
a second functional module from the multiple functional modules, wherein the second functional module contains a signal path that has an intermediate stage and an output stage that couples the intermediate stage to the first functional module; and
a detection and control module programmed to detect activity along the intermediate stage and control power to the first functional module based on the detected activity.

31. The system of claim 30, wherein the detection and control module comprises:
an activity detector coupled to the intermediate stage for detecting a signal along the intermediate stage;
a power control block coupling the first functional module to a power source; and
an energy controller coupled to the activity detector and to the power control block, wherein the energy controller is programmed to control the power control block to reduce power to the first functional module when no signal is detected for a pre-determined number of successive clock cycles along the intermediate stage and to apply power to the first functional module when a signal is detected along the intermediate stage.

32. The system of claim 30, wherein the first and second functional modules comprise any one or more of co-processors, an arithmetic module, a graphics module, and a digital signal processing module.

33. The system of claim 30, wherein the multiple functional modules are formed on a single semiconductor die.

34. A method of controlling power to first and second functional modules comprising:
monitoring activity along an intermediate stage of a signal path on the first functional module, the signal path also having an output stage that couples the first functional module to the second functional module; and
controlling power to the second functional module based on the detected activity.

35. The method of claim 34, wherein controlling power to the second functional module comprises applying power to the second functional module when activity is detected along the intermediate stage and reducing power to the second functional module when no activity is detected along the intermediate stage for a pre-determined period.

36. The method of claim 34, wherein the first and second functional modules comprise any one or more of co-processors, an arithmetic module, a graphics module, and a digital signal processing module.

37. The method of claim 34, wherein the first and second functional modules are formed on a single semiconductor die.

38. A semiconductor die comprising:
a. multiple functional modules; and
b. one or more monitors for detecting activity on the multiple functional modules.

39. The semiconductor die of claim 38, further comprising a controller for controlling the multiple functional modules in response to the detected activity.

40. The semiconductor die of claim 39, wherein the controller is programmed to control power to the multiple functional modules.

41. The semiconductor die of claim 39, wherein the controller is programmed to control loads to the multiple functional modules.

42. The semiconductor die of claim 41, wherein the controller is programmed to balance the loads to the multiple functional modules.
